(19) United States
(12) Patent Application Publication
(10) Pub. No.: US 2025/0300077 A1
(43) Pub. Date: Sep. 25, 2025

(54) END-TO-END REDUCTION BETWEEN SEMICONDUCTOR INTERCONNECTS

(71) Applicant: Intel Corporation, Santa Clara, CA (US)

(72) Inventors: Sheng-Po Fang, Vancouver, WA (US); Lee D. Rockford, Portland, OR (US); Guillaume Bouche, Portland, OR (US)

(73) Assignee: Intel Corporation, Santa Clara, CA (US)

(21) Appl. No.: 18/613,942

(22) Filed: Mar. 22, 2024

(51) Int. Cl. H01L 23/528

(52) U.S. Cl. CPC H01L 23/5283

(57) ABSTRACT

Techniques for forming semiconductor interconnects within a given interconnect layer that have reduced end-to-end (ETE) spacing between adjacent interconnects. In an example, an interconnect layer includes a first metal line extending lengthwise along a first direction, and a second metal line extending lengthwise collinearly with the first metal line along the first direction. A body of dielectric material is between the first metal line and the second metal line along the first direction. A third metal line extending lengthwise along the first direction is adjacent to and parallel with the first metal line and the second metal line, wherein the third metal line includes a protrusion extending outward in a second direction from a sidewall of the third metal line and toward the body of dielectric material. The protrusion is aligned with the dielectric body along the second direction. The first and second directions may be orthogonal to one another.

### BACKGROUND

As integrated circuits continue to scale downward in size, a number of challenges arise. As density of devices increases, the available space on a given die dwindles rapidly. Additionally, interconnects must be formed to contact various device elements for routing signal and power to the devices. As the logic standard cell size also continues to decrease, forming the interconnects with desired dimensions and density becomes challenging. Accordingly, there remain a number of non-trivial challenges with respect to fabricating certain structures in an integrated circuit.

### BRIEF DESCRIPTION OF THE DRAWINGS

FIG. 1 is a cross-sectional view that illustrates an example portion of an integrated circuit configured with an interconnect region over a plurality of semiconductor devices, in accordance with an embodiment of the present disclosure.

FIG. 2 is a plan view of a single interconnect layer of the interconnect region of FIG. 1 that illustrates a reduced end-to-end spacing between adjacent interconnects, in accordance with an embodiment of the present disclosure.

FIGS. 3A-3C are plan and cross-sectional views of one stage of an example process for forming an interconnect layer with a reduced end-to-end spacing between adjacent interconnects, in accordance with some embodiments of the present disclosure.

FIGS. 4A-4C are plan and cross-sectional views of another stage of the example process for forming an interconnect layer with a reduced end-to-end spacing between adjacent interconnects, in accordance with some embodiments of the present disclosure.

FIGS. 5A-5C are plan and cross-sectional views of another stage of the example process for forming an interconnect layer with a reduced end-to-end spacing between adjacent interconnects, in accordance with some embodiments of the present disclosure.

FIGS. 6A-6C are plan and cross-sectional views of another stage of the example process for forming an interconnect layer with a reduced end-to-end spacing between adjacent interconnects, in accordance with some embodiments of the present disclosure.

FIGS. 7A-7C are plan and cross-sectional views of another stage of the example process for forming an interconnect layer with a reduced end-to-end spacing between adjacent interconnects, in accordance with some embodiments of the present disclosure.

FIGS. 8A-8C are plan and cross-sectional views of another stage of the example process for forming an interconnect layer with a reduced end-to-end spacing between adjacent interconnects, in accordance with some embodiments of the present disclosure.

FIGS. 9A-9C are plan and cross-sectional views of another stage of the example process for forming an interconnect layer with a reduced end-to-end spacing between adjacent interconnects, in accordance with some embodiments of the present disclosure.

FIGS. 10A-10C are plan and cross-sectional views of another stage of the example process for forming an interconnect layer with a reduced end-to-end spacing between adjacent interconnects, in accordance with some embodiments of the present disclosure.

FIGS. 11A-11C are plan and cross-sectional views of another stage of the example process for forming an interconnect layer with a reduced end-to-end spacing between adjacent interconnects, in accordance with some embodiments of the present disclosure.

FIG. 12 illustrates a cross-section view of a chip package containing one or more semiconductor dies, in accordance with an embodiment of the present disclosure.

FIG. 13 is a flowchart of a fabrication process for an interconnect region having an interconnect layer with a reduced end-to-end spacing between adjacent interconnects, in accordance with an embodiment of the present disclosure.

FIG. 14 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein for forming semiconductor interconnects within a given interconnect layer that have reduced end-to-end (ETE) spacing between adjacent interconnects. The techniques can be implemented with little or no need for additional masking steps. The techniques can be used in any number of integrated circuit applications are particularly useful with respect to forming interconnects above transistor devices. According to an embodiment, an interconnect layer includes a plurality of metal interconnects extending in a first direction along any number of parallel tracks (also called colors). The spacing between the respective ends of two adjacent interconnects of the same color (within the same track, so as to be colinear with one another) may be reduced by using a directional tilted etch and tone-inversion process with a sacrificial material to form hard mask spacer structures. The tone-inversion process effectively allows for inverse patterns, such as the case where a given elongated space is converted into a line or a hole is converted into a post. Numerous configurations and variations will be apparent in light of this disclosure.

### General Overview

As previously noted above, it can be challenging to provide densely packed interconnect structures given the footprint limitations on a die. Various masking and etching techniques can be used to provide small ETE spacing between adjacent interconnects, but such techniques require the use of additional masking steps and lithography steps, increasing the complexity and fabrication cost of the device. Furthermore, physical limitations on mask pattern sizes can create limits on the ETE spacing.

Thus, techniques are provided herein for forming interconnects having a reduced ETE spacing between adjacent interconnects of the same color. The interconnects may be part of a single interconnect layer of a back-end-of-the-line (BEOL) interconnect region over a device layer that includes a plurality of semiconductor devices. The interconnect layer may be, for instance, one of the lower interconnect layers of the interconnect region where the density of interconnects is at its highest, such as the first interconnect layer (e.g., Metal 0) or second interconnect layer (e.g., Metal 1). According to some embodiments, one or more hard mask layers are deposited over a dielectric layer and are patterned to determine the locations of the metal interconnect lines within the dielectric layer. During the process, a sacrificial material is deposited within etched regions of one or more of the mask layers. A first mask layer is removed and spacer structures are then formed on sidewalls of the sacrificial material that were exposed following the removal of the first mask layer. These spacer structures are also formed on a second mask layer, and are used to transfer the interconnect line pattern into the second mask layer following the removal of the sacrificial material. This process allows for small ETE spacing between adjacent interconnect lines (e.g., less than 15 nm, less than 10 nm, or between 5 and 15 nm), relative to existing techniques.

According to some embodiments, the spacer structures formed around the ends of colinear lines of sacrificial material merge together and create a natural divot, which is transferred into the underlying second mask layer. The resulting metal interconnect lines adjacent to the ETE region (e.g., the dielectric plug between the colinear metal interconnect lines) will have a corresponding protrusion extending towards the ETE region (e.g., towards a center of the ETE region). These protrusions can be readily observed at any given ETE region across the interconnect layer.

According to an embodiment, an integrated circuit includes a plurality of semiconductor devices, an interconnect region above the plurality of semiconductor devices having a plurality of interconnect layers, and an interconnect layer of the plurality of stacked interconnect layers. The interconnect layer includes a first metal line extending length wise along a first direction, a second metal line extending lengthwise collinearly with the first metal line along the first direction, a dielectric plug between the first metal line and the second metal line along the first direction, and a third metal line extending lengthwise along the first direction adjacent to and parallel with the first metal line and the second metal line. The third metal line includes a protrusion extending outward from a sidewall of the third metal line. The protrusion is aligned with the dielectric plug along a second direction orthogonal to the first direction.

According to an embodiment, an integrated circuit includes an interconnect region above a plurality of semiconductor devices and having a plurality of stacked interconnect layers, and an interconnect layer of the plurality of stacked interconnect layers. The interconnect layer includes a dielectric layer and a plurality of metal lines within at least a portion of the dielectric layer. The plurality of metal lines includes a first metal line extending lengthwise along a first direction and a second metal line extending lengthwise along the first direction adjacent to and parallel with the first metal line. The second metal line has a protrusion extending outward from a sidewall of the second metal line. The dielectric layer includes a dielectric plug at an end of the first metal line along the first direction. The protrusion is aligned with the dielectric plug along a second direction orthogonal to the first direction.

According to another embodiment, a method of forming an interconnect layer of an integrated circuit includes forming a first mask layer over a dielectric layer; forming a second mask layer over the first mask layer; etching the first and second mask layers to form a first trench and a second trench through both the first and second mask layers with the first trench extending collinearly with the second trench along a first direction and with a portion of the first and second mask layers between the first trench and the second trench along the first direction; filling the first trench and the second trench with a sacrificial material; removing the second mask layer; forming a dielectric material over the first mask layer and over the sacrificial material; etching the dielectric material such that the dielectric material remains on sidewalls of the sacrificial material; removing the sacrificial material; removing portions of the first mask layer not protected by the dielectric material; etching trench recesses into regions of the dielectric layer not protected by the first mask layer; and forming conductive lines within the trench recesses.

The techniques can be used with any type of planar and non-planar transistors, including finFETs (sometimes called double-gate transistors, or tri-gate transistors), nanowire and nanoribbon transistors (sometimes called gate-all-around transistors), and thin film transistors, to name a few examples. The source and drain regions can be, for example, implantation doped portions of the substrate or fin structure, or epitaxial regions that are deposited during an etch-and-replace source/drain forming process. The dopant-type in the source and drain regions will depend on the polarity of the corresponding transistor. The gate structure can be implemented with a gate-first process or a gate-last process (sometimes called a remove metal gate, or RMG, process). Any number of semiconductor materials can be used in forming the transistors to which signal or power is being supplied by any of the interconnects described herein, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate the presence of at least one metal line in a given interconnect layer that has a protrusion from a sidewall of the metal line towards a dielectric plug between the ends of adjacent colinear metal lines. The protrusion may be horn shaped with a tip that is aligned with a center of the dielectric plug. In some examples, the ETE spacing between the adjacent colinear metal lines may be observed as being less than 15 nm, less than 10 nm, or between 5 and 15 nm. A dielectric plug or body may reside within the ETE spacing.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer.

### Architecture

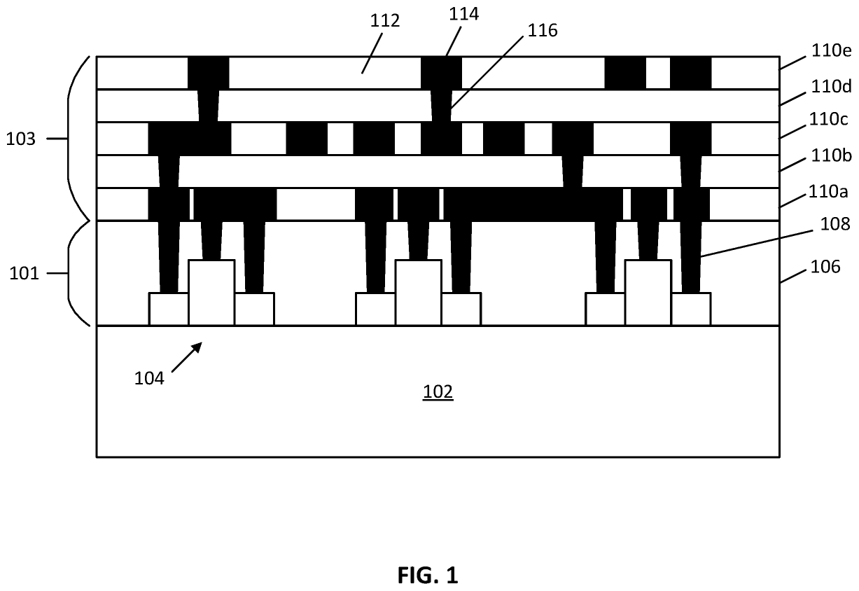

FIG. 1 is a cross-sectional view that illustrates an example portion of an integrated circuit having an interconnect region above a plurality of semiconductor devices, in accordance with an embodiment of the present disclosure. The semiconductor devices in this example are non-planar metal oxide semiconductor (MOS) transistors, such as tri-gate or gate-all-around (GAA) transistors, although other transistor topologies and types can also benefit from the techniques provided herein, as will be appreciated (e.g., planar transistors, forksheet transistors, thin film transistors, or any other transistors to which contact can be made).

According to some embodiments, the integrated circuit includes a device region 101 (sometimes referred to as a device layer), and an interconnect region 103 over the device region 101. Device region 101 may include a plurality of semiconductor devices 104 along with one or more other layers or structures associated with the semiconductor devices 104. For example, device region 101 can also include one or more dielectric layers 106 that surround active portions or contacts of the semiconductor devices 104. Device region 101 may also include one or more conductive contacts 108 that provide electrical contact to transistor elements such as gate structures, drain regions, or source regions. Conductive contacts 108 include, for example, tungsten, although other metal or metal alloy materials may be used as well. Conductive contacts may also be a part of, or otherwise include, what is sometimes called a local interconnect, which is considered part of the device layer and usually formed prior to any backend processing.

In some embodiments, device region 101 is formed on or over a substrate 102. Substrate 102 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, the substrate can be a semiconductor-on-insulator substrate having a desired semiconductor layer over a buried insulator layer (e.g., silicon over silicon dioxide). Alternatively, the substrate can be a multilayer substrate or superlattice suitable for forming nanowires or nanoribbons (e.g., alternating layers of silicon and SiGe, or alternating layers indium gallium arsenide and indium phosphide). Any number of substrates can be used. In some embodiments, backside processing is used to remove substrate 102 and form any number of backside interconnect layers.

Interconnect region 103 includes a plurality of interconnect layers 110a-110e stacked over one another. Each interconnect layer can include a dielectric material 112 along with one or more different conductive features. Dielectric material 112 can be any dielectric, such as silicon oxide, silicon oxycarbide, silicon nitride, or silicon oxynitride. Dielectric material 112 may be deposited using any known dielectric deposition technique such as chemical vapor deposition (CVD), plasma-enhanced chemical vapor deposition (PECVD), flowable CVD, spin-on dielectric, or atomic layer deposition (ALD). The one or more conductive features can include conductive traces 114 and conductive vias 116 arranged in any pattern across the interconnect layers 110a-110e to carry signal and/or power voltages to/from the various semiconductor devices 104. A conducive via, such as conductive via 116, may extend through an interconnect layer to connect between conductive traces on an upper interconnect layer and a lower interconnect layer. In other cases, a via 116 may only extend part way through a given interconnect layer. Although interconnect region 103 is illustrated with only five interconnect layers, any number of interconnect layers can be used within interconnect region 103. Also, this example shows vias and lines in different interconnect layers, in both single and dual damascene configurations. In other examples, vias and lines may also exist within the same interconnect layer, such as in the case of some dual damascene configurations.

Any of conductive traces 114 and conductive vias 116 can include any number of conductive materials, with some examples including copper, ruthenium, tungsten, cobalt, molybdenum, and alloys thereof. In some cases, any of conductive traces 114 and conductive vias 116 include a relatively thin liner or barrier, such as titanium nitride, titanium silicide, tungsten carbo-nitride (WCN), PVD or ALD tungsten, or tantalum nitride. As will be discussed in more detail herein, any of conductive vias 116 may include a MIM structure as part of the conductive via to provide an anti-fuse element within interconnect region 103.

It should be noted that each of the various conductive vias 116 and conductive contacts 108 are shown with tapered profiles to indicate a more natural appearance due to the etching process used to form the openings. Any degree of tapering may be observed depending on the etch parameters used and the thickness of the dielectric layer being etched through. Furthermore, conductive vias may be stacked one over the other through different dielectric layers of interconnect region 103. However, in some examples, a single via recess may be formed through more than one dielectric layer yielding a taller, more tapered conductive via that extends through two or more dielectric layers.

The various interconnect layers of interconnect region 103 may not all be the same thickness. According to some embodiments, the interconnect layers increase in thickness moving upwards towards the top of interconnect region 103. Thus, the top-most interconnect layer may have the greatest thickness while the bottom-most interconnect layer may have the smallest thickness. In some examples, the top-most interconnect layer may have a thickness in the range of several micrometers (e.g., 1-4 μm), while the bottom-most interconnect layer may have a thickness of less than 50 nm.

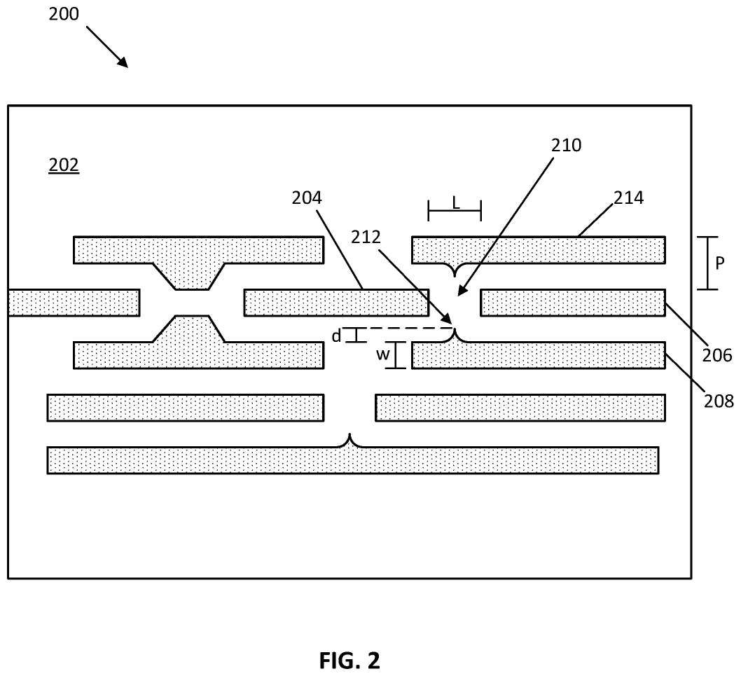

FIG. 2 illustrates a plan view of a portion of a single interconnect layer 200, according to some embodiments. Interconnect layer 200 may, for example, be a portion of any of the interconnect layers discussed above in FIG. 1. Accordingly, interconnect layer 200 includes a dielectric layer 202 and any number of metal lines extending lengthwise parallel to each other along different tracks (or colors). Dielectric layer 202 can be any dielectric, such as silicon oxide, silicon oxycarbide, silicon nitride, or silicon oxynitride. In the illustrated example, interconnect layer 200 includes a first metal line 204, a second metal line 206 that is colinear to first metal line 204, and a third metal line 208 that is adjacent to, and parallel with, both first metal line 204 and second metal line 206. Each of metal lines 204/206/208 can include any number of conductive materials, with some examples including copper, ruthenium, tungsten, cobalt, molybdenum, and alloys thereof.

According to some embodiments, dielectric layer 202 includes a dielectric plug 210 between the ends of first metal line 204 and second metal line 206 (e.g., an ETE region). Dielectric plug 210 more generally may be a body of dielectric material. Dielectric plug 210 has an ETE length L that is preferably as small as possible to maximize packing density of the interconnects. By using the fabrication procedure described herein, the ETE length L can be reduced to less than 15 nm, less than 10 nm, or between 5 and 15 nm (e.g., between 5 and 10, or between 10 and 15. Each metal line 204/206/208 may have a total width w₁ between about 10 nm and about 15 nm, and adjacent metal lines of different colors may have a pitch P between about 15 nm and about 25 nm.

According to some embodiments, third metal line 208 includes a protrusion 212 extending away from its sidewall as a result of the fabrication process described herein. Protrusion 212 is generally aligned with dielectric plug 210 along a second direction that is orthogonal to the first direction. In some such cases, protrusion 212 may be aligned along a central axis of dielectric plug 210 (e.g., along the second direction orthogonal to the first direction). In some examples, protrusion 212 has a horn shape or a wedge shape with its outermost point aligned along the central axis of dielectric plug 210. Protrusion 212 may extend away from the sidewall of third metal line 208 by a distance d between, for example, about 2 nm and about 5 nm, between about 2 nm and about 3 nm, or between about 1 nm and about 3 nm. It should be noted that a fourth metal line 214 may also be provided on the opposite side of dielectric plug 210 from third metal line 208, and may include a same protrusion on its sidewall extending towards dielectric plug 210. In some such examples, the protrusion from fourth metal line 214 may be aligned with protrusion 212 of third metal line 208 along the second direction. In still other such examples, protrusion 212 has an outermost portion that is farthest from the sidewall of third metal line 208, and the opposing protrusion of fourth metal line 214 has an outermost portion that is farthest from the sidewall of fourth metal line 214, and a plane extending in the second direction passes through each of the outermost portions of protrusion 212, the outermost portion of the opposing protrusion, and dielectric plug 210.

### Fabrication Methodology

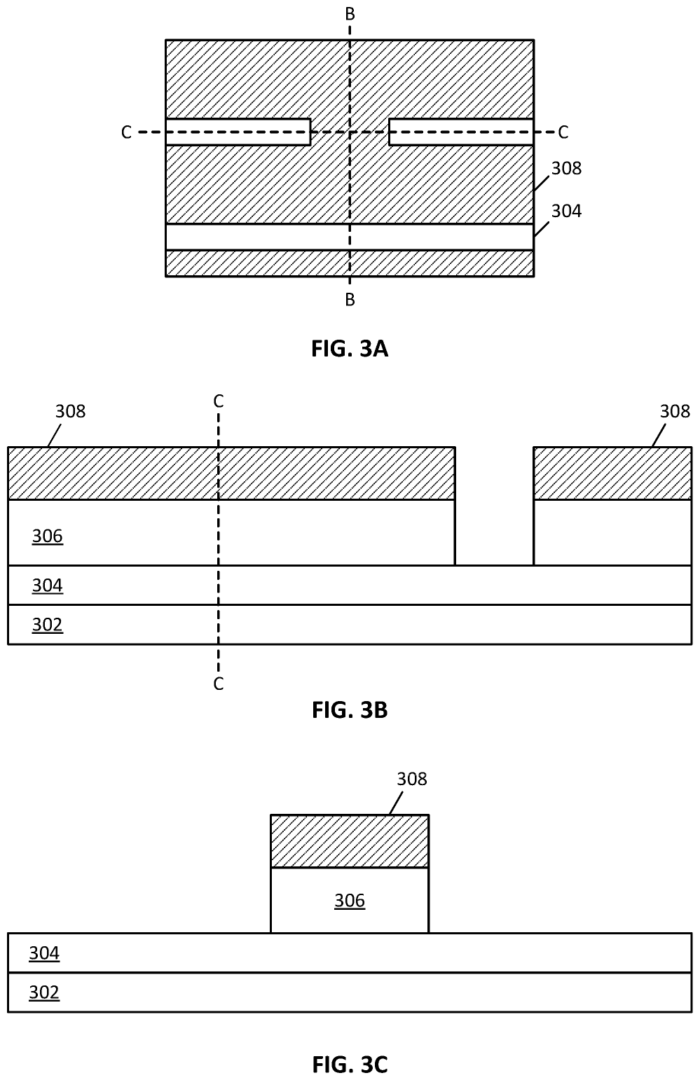

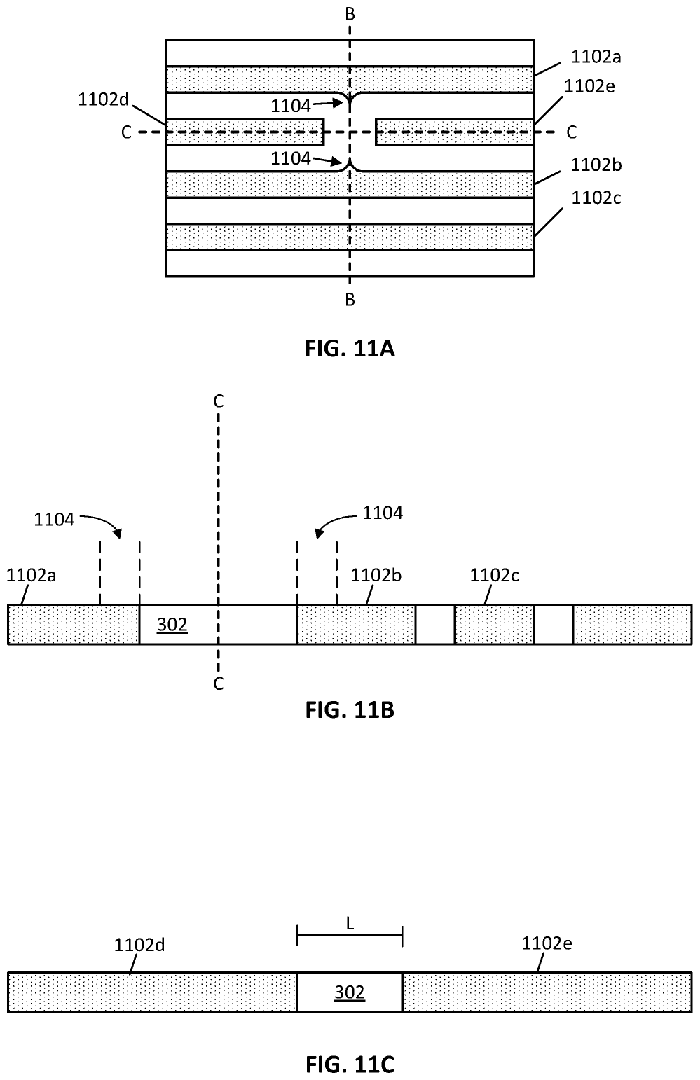

FIGS. 3A-11A, 3B-11B, and 3C-11C are plan and cross-sectional views that collectively illustrate an example process for forming a portion of an interconnect region of an integrated circuit, in accordance with an embodiment of the present disclosure. FIGS. 3A-11A represent plan views of a single interconnect layer, while FIGS. 3B-11B represent a cross-sectional view taken across the B-B line from the plan view, and FIGS. 3C-11C represent a cross-sectional view taken across the C-C line from the plan view. Each figure shows an example structure that results from the process flow up to that point in time, so the depicted structure evolves as the process flow continues, culminating in the structure shown in FIGS. 11A, 11B, and 11C. Such a structure may be part of an overall integrated circuit (e.g., such as a processor or memory chip) that includes, for example, digital logic cells and/or memory cells and analog mixed signal circuitry. Thus, the illustrated integrated circuit structure may be part of a larger integrated circuit that includes other integrated circuitry not depicted. Example materials and process parameters are given, but the present disclosure is not intended to be limited to any specific such materials or parameters, as will be appreciated. Figures sharing the same number (e.g., FIGS. 3A, 3B, and 3C) illustrate different views of the structure at the same point in time during the process flow.

FIGS. 3A-3C illustrate plan and cross-section views of a portion of an interconnect layer (e.g., a metal 0 or metal 1 layer) with various mask layers over a dielectric layer 302, according to some embodiments. Dielectric layer 302 may be any suitable dielectric material, such as silicon oxide, silicon oxycarbide, silicon nitride, or silicon oxynitride. Two mask layers are deposited over dielectric layer 302, according to some embodiments. A first mask layer 304 is deposited on dielectric layer 302 and a second mask layer 306 is deposited on first mask layer 304. Each of first mask layer 304 and second mask layer 306 may be hard mask layers that include any suitable dielectric material, such as silicon nitride or silicon oxynitride. In some examples, first mask layer 304 has a material composition that is different from second mask layer 306 to provide an adequate degree of etch selectivity between first mask layer 304 and second mask layer 306. In one example, first mask layer 304 includes silicon nitride and second mask layer 306 includes silicon dioxide.

According to some embodiments, a mask material 308 is deposited over second mask layer 306 and lithographically patterned to form trenches in the regions where some of the conductive lines of the interconnect layer will eventually be formed through dielectric layer 302. A reactive ion etching (RIE) process may be performed to transfer the pattern in mask material 308 to the underlying second mask layer 306, thus exposing the top surface of first mask layer 304. Mask material 308 may be a hard mask layer or a suitable photoresist.

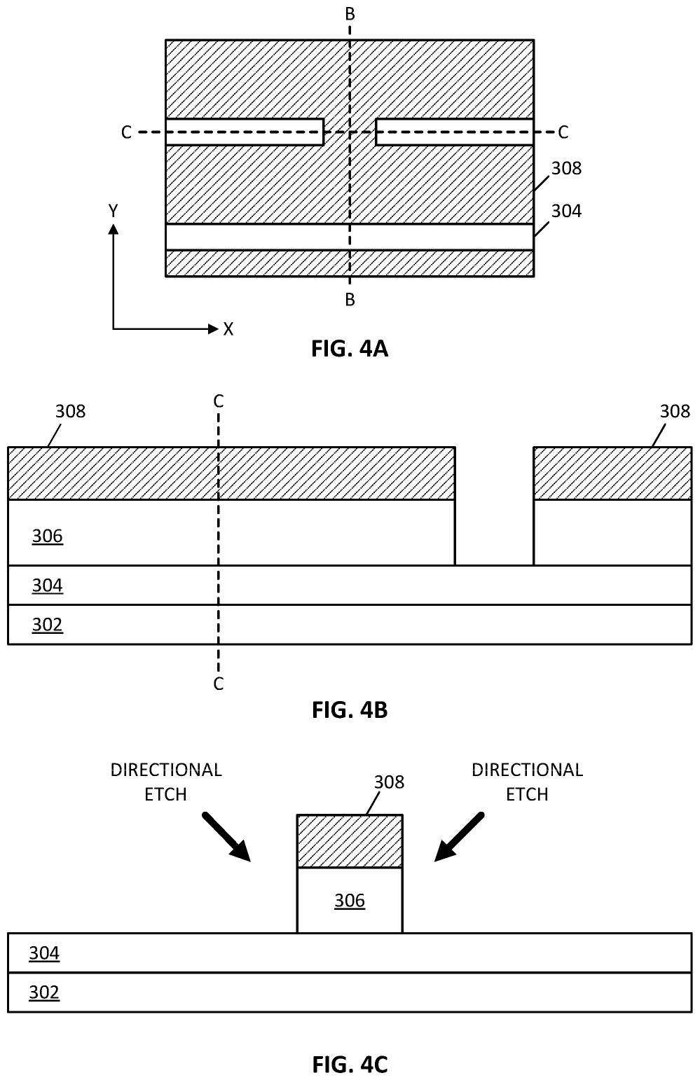

FIGS. 4A-4C illustrate plan and cross-section views of the interconnect layer of FIGS. 3A-3C following a directional etch process to reduce the lateral width of second mask layer 306, according to some embodiments. As shown in the cross-section of FIG. 4C, a directional tilted etch may be performed that laterally removes portions of second mask layer 306 (and mask material 308) along one direction, but does not etch (or etches very little) along the orthogonal direction. In the illustrated example, the directional etch process may preferentially etch exposed sidewalls of second mask layer 306 that extend along the Y-direction. The directional etch may be performed by an RIE process with the ionizing energy tilted at an angle of, for example, 30°, 45°, 60°, or 75°, although other angles may be used. The directional etch process may be performed to reduce the ETE spacing between the eventual metal lines to be formed through dielectric layer 302 on either side of second mask layer 306.

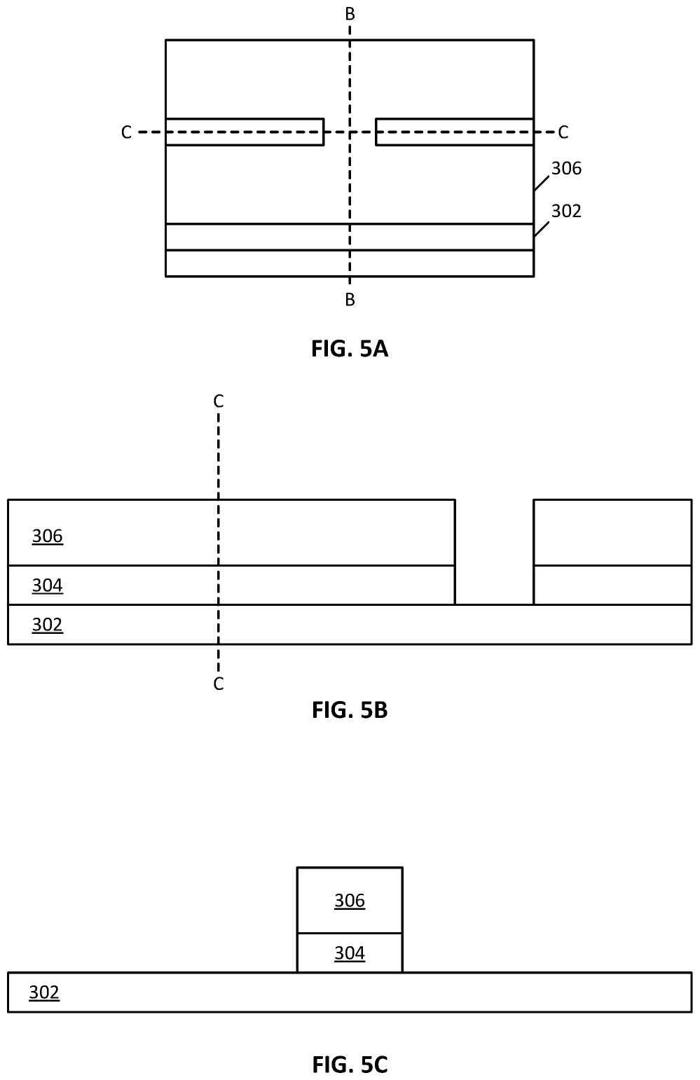

FIGS. 5A-5C illustrate plan and cross-section views of the interconnect layer of FIGS. 4A-4C following the transfer of the pattern in second mask layer 306 into first mask layer 304 and the removal of mask material 308, according to some embodiments. Another RIE process may be used to transfer the pattern within second mask layer 306 to the underlying first mask layer 304. At this point, a top surface of dielectric layer 302 is exposed at the bottom of each of the patterned trenches through both first mask layer 304 and second mask layer 306. Mask material 308 can be removed using any suitable isotropic etching process.

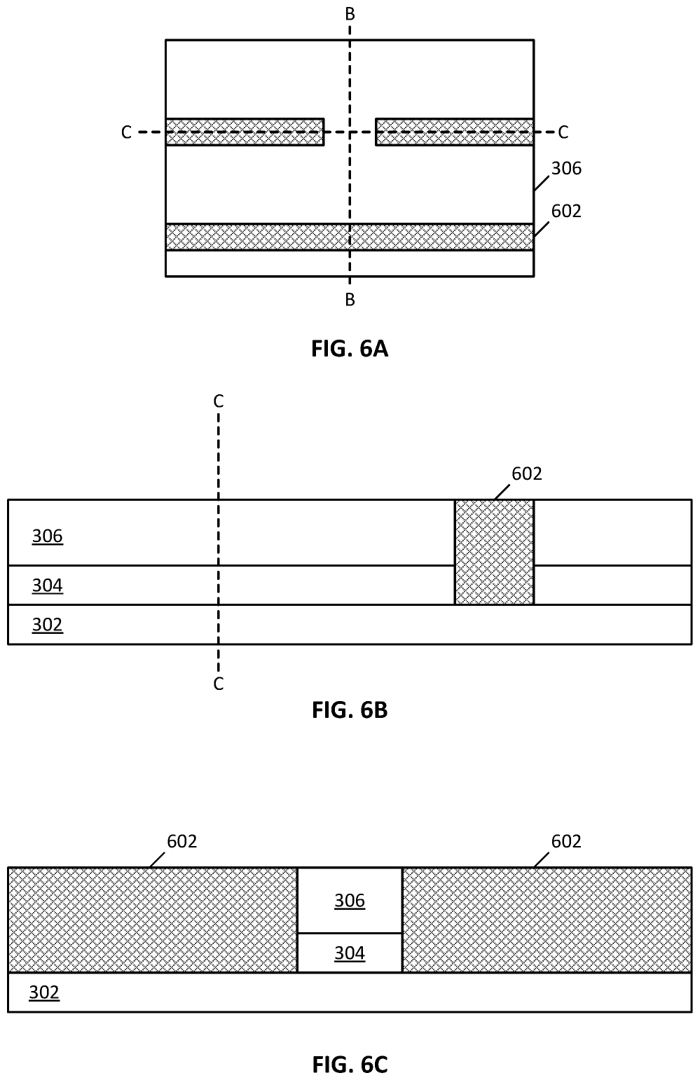

FIGS. 6A-6C through 9A-9C collectively illustrate a tone-inversion process, according to some embodiments. In more detail, FIG. 6A-6C illustrate plan and cross-section views of the interconnect layer of FIGS. 5A-5C following the formation of a sacrificial material within the patterned trenches through first mask layer 304 and second mask layer 306, according to some embodiments. Sacrificial material 602 may be any suitable material that can be removed at a later time without damaging the surrounding material layers. In one example, sacrificial material 602 is carbon hard mask (CHM). Other materials such as aluminum oxide may be used as well. According to some embodiments, sacrificial material 602 is deposited using any suitable vapor deposition technique or spin-on technique and is polished using, for example, chemical mechanical polishing (CHM) such that a top surface of sacrificial material 602 is substantially coplanar with a top surface of second mask layer 306.

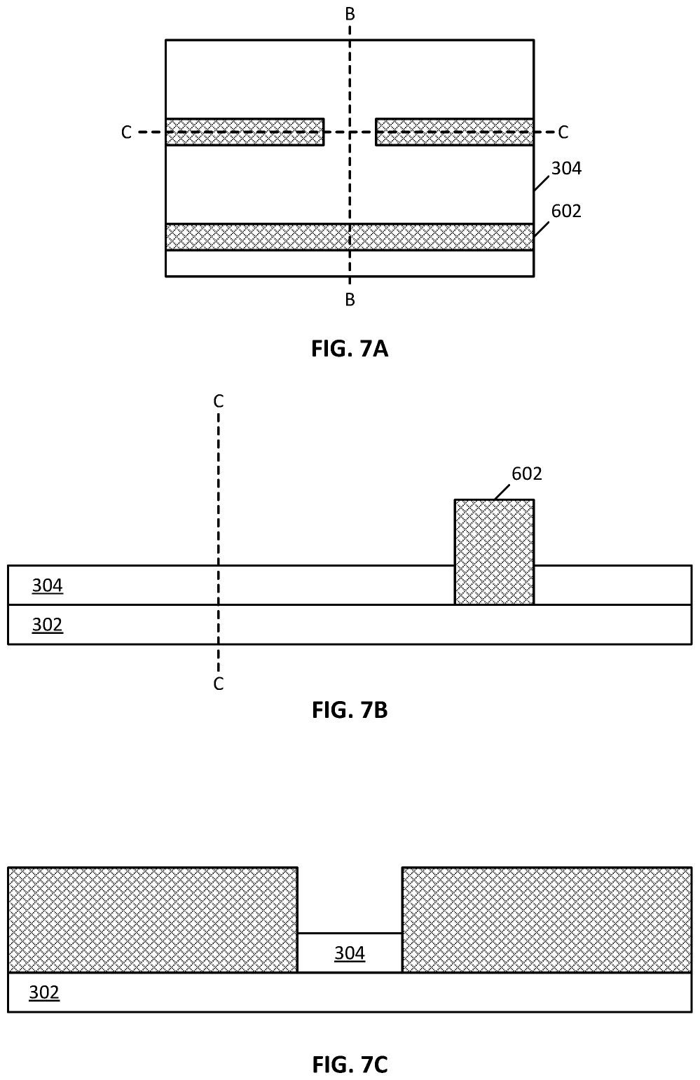

FIGS. 7A-7C illustrate plan and cross-section views of the interconnect layer of FIGS. 6A-6C following the removal of second mask layer 306, according to some embodiments. Any suitable isotropic etching process may be used to selectively remove second mask layer 306, while sacrificial material 602 remains. As a result, sacrificial material 602 extends above a top surface of first mask layer 304 in areas where some of the metal lines will eventually be formed through dielectric layer 302.

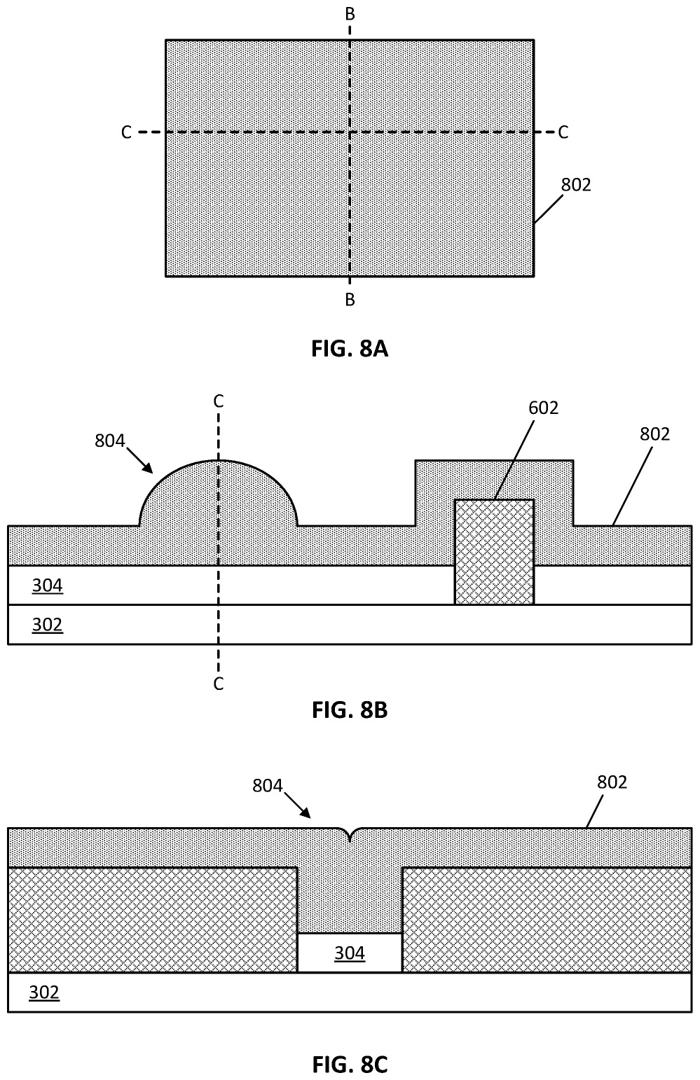

FIGS. 8A-8C illustrate plan and cross-section views of the interconnect layer of FIGS. 7A-7C following the formation of spacer material 802 across the interconnect layer, according to some embodiments. Spacer material 802 may be any suitable dielectric material. In some embodiments, spacer material 802 has a different material composition compared to first mask layer 304 to provide an adequate degree of etch selectivity between first mask layer 304 and spacer material 802. In one example, spacer material 802 includes silicon dioxide and first mask layer 304 includes silicon nitride or silicon oxynitride.

According to some embodiments, spacer material 802 is deposited using any suitable conformal deposition technique, such as atomic layer deposition (ALD) or plasma-enhanced chemical vapor deposition (PECVD). Accordingly, spacer material 802 forms along the exposed sidewalls of sacrificial material 602. Spacer material 802 merges together between the sidewalls of adjacent, colinear lines of sacrificial material as seen in the cross-section of FIG. 8C. This merged region 804 of spacer material 802 is also seen in the cross-section of FIG. 8B.

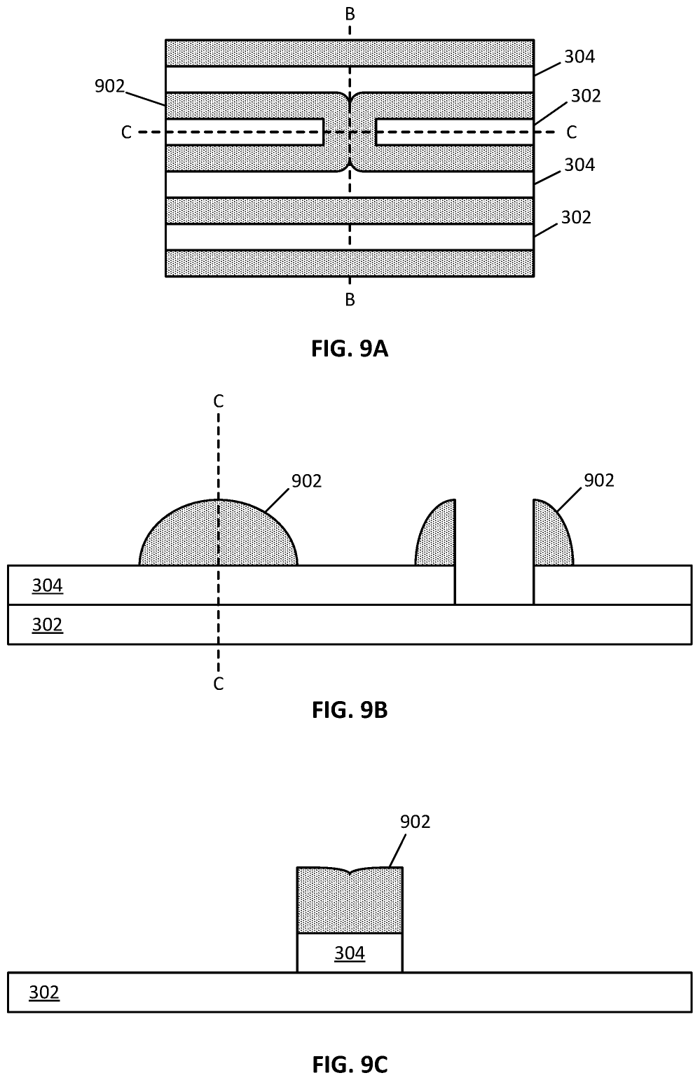

FIGS. 9A-9C illustrate plan and cross-section views of the interconnect layer of FIGS. 8A-8C following etching back of spacer material 802 and removal of sacrificial material 602, according to some embodiments. An RIE process may be used to remove portions of spacer material 802 not present on the sidewalls of sacrificial material 602. As a result, spacer structures 902 remain from the portions of spacer material 802 that were present on the sidewalls of sacrificial material 602. Sacrificial material 602 may be removed using any suitable isotropic etching or wet clean process, or ashing in the example where sacrificial material 602 is CHM.

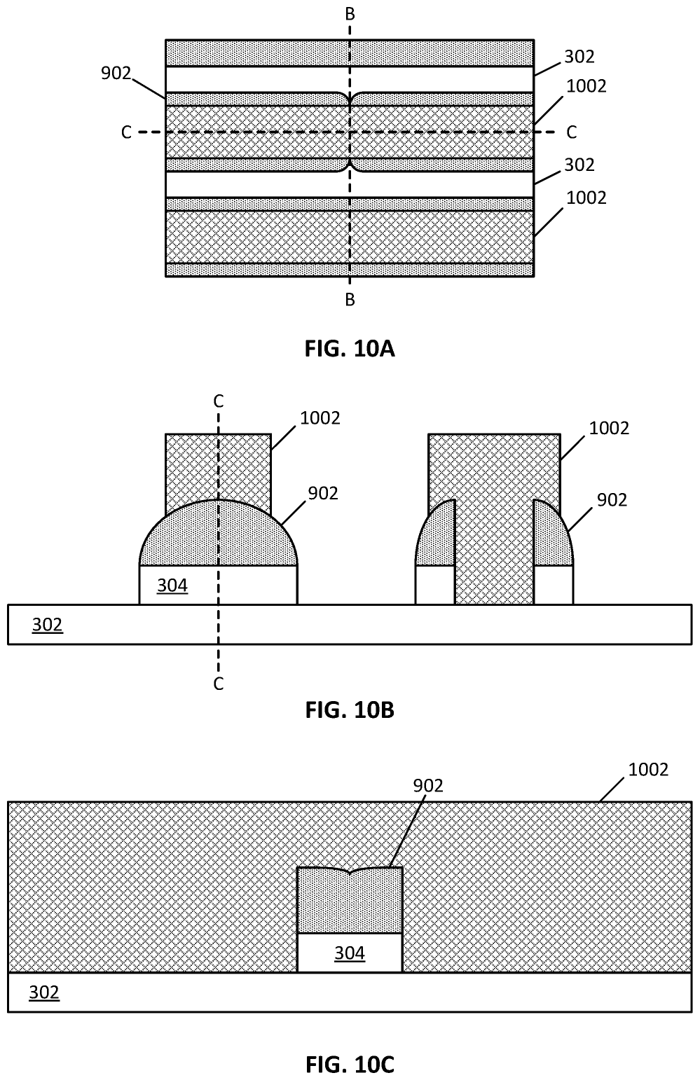

FIGS. 10A-10C illustrate plan and cross-section views of the interconnect layer of FIGS. 9A-9C following the formation of mask structure 1002 to protect any exposed areas of dielectric layer 302, according to some embodiments. Mask structure 1002 may be formed in strips over the exposed top surfaces of dielectric layer 302 across the interconnect layer as shown in FIG. 10A. Mask structure 1002 may be any suitable hard mask material or photoresist. In some embodiments, mask structure 1002 is CHM. According to some embodiments, following the formation of mask structure 1002, any exposed portions of first mask layer 304 (e.g., not protected by spacer structures 902) may be removed using an RIE process.

FIGS. 11A-11C illustrate plan and cross-section views of the interconnect layer of FIGS. 10A-10C following the removal of mask structure 1002 and formation of metal lines within dielectric layer 302, according to some embodiments. According to some embodiments, trenches in dielectric layer 302 are formed in all areas not protected by first mask layer 304 (e.g., the pattern of first mask layer 304 dictates the metal line pattern of the interconnect layer). An RIE process may be used to transfer the first mask layer 304 pattern into dielectric layer 302. The trenches etched into dielectric layer 302 may be filled with a suitable conductive material to form metal lines, such as metal lines 1102a-1102e in the illustrated example. First mask layer 304 may be removed prior to the deposition of the conductive material within the trenches or after the deposition of the conductive material within the trenches.

Due to the use of spacer structures 902 to provide the pattern for the metal line locations, protrusions 1104 extend from the sidewalls of metal lines 1102a and 1102b towards the dielectric region between the opposing ends of metal lines 1102d and 1102e. The additional width provided by protrusions 1104 on metal lines 1102a and 1102b is shown in FIG. 11B. According to some embodiments, this additional width may be between 1 nm and 3 nm, between 2 and 3 nm, or between 3 nm and 5 nm. According to some embodiments, the ETE spacing L between metal lines 1102d and 1102e is between 10 nm and 15 nm, between 5 nm and 10 nm, or between 15 nm and 20 nm.

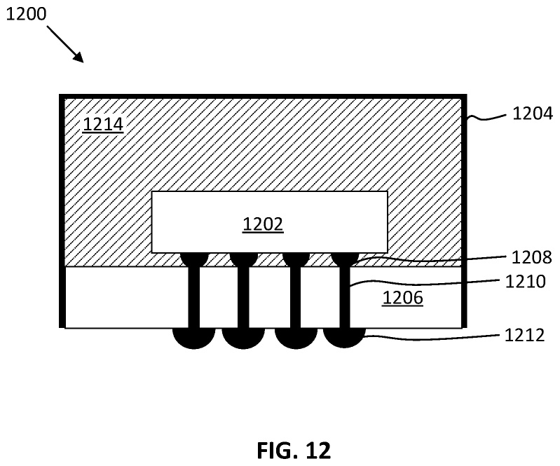

FIG. 12 illustrates an example embodiment of a chip package 1200, in accordance with an embodiment of the present disclosure. As can be seen, chip package 1200 includes one or more dies 1202. One or more dies 1202 may include at least one integrated circuit having a structure as described in any of the aforementioned embodiments. One or more dies 1202 may include any other circuitry used to interface with other devices formed on the dies, or other devices connected to chip package 1200, in some example configurations.

As can be further seen, chip package 1200 includes a housing 1204 that is bonded to a package substrate 1206. The housing 1204 may be any standard or proprietary housing, and may provide, for example, electromagnetic shielding and environmental protection for the components of chip package 1200. The one or more dies 1202 may be conductively coupled to a package substrate 1206 using connections 1208, which may be implemented with any number of standard or proprietary connection mechanisms, such as solder bumps, ball grid array (BGA), pins, or wire bonds, to name a few examples. Package substrate 1206 may be any standard or proprietary package substrate, but in some cases includes a dielectric material having conductive pathways (e.g., including conductive vias and lines) extending through the dielectric material between the faces of package substrate 1206, or between different locations on each face. In some embodiments, package substrate 1206 may have a thickness less than 1 millimeter (e.g., between 0.1 millimeters and 0.5 millimeters), although any number of package geometries can be used. Additional conductive contacts 1212 may be disposed at an opposite face of package substrate 1206 for conductively contacting, for instance, a printed circuit board (PCB). One or more vias 1210 extend through a thickness of package substrate 1206 to provide conductive pathways between one or more of connections 1208 to one or more of contacts 1212. Vias 1210 are illustrated as single straight columns through package substrate 1206 for ease of illustration, although other configurations can be used (e.g., damascene, dual damascene, through-silicon via, or an interconnect structure that meanders through the thickness of substrate 1206 to contact one or more intermediate locations therein). In still other embodiments, vias 1210 are fabricated by multiple smaller stacked vias, or are staggered at different locations across package substrate 1206. In the illustrated embodiment, contacts 1212 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 1212, to inhibit shorting.

In some embodiments, a mold material 1214 may be disposed around the one or more dies 1202 included within housing 1204 (e.g., between dies 1202 and package substrate 1206 as an underfill material, as well as between dies 1202 and housing 1204 as an overfill material). Although the dimensions and qualities of the mold material 1214 can vary from one embodiment to the next, in some embodiments, a thickness of mold material 1214 is less than 1 millimeter. Example materials that may be used for mold material 1214 include epoxy mold materials, as suitable. In some cases, the mold material 1214 is thermally conductive, in addition to being electrically insulating.

### Methodology

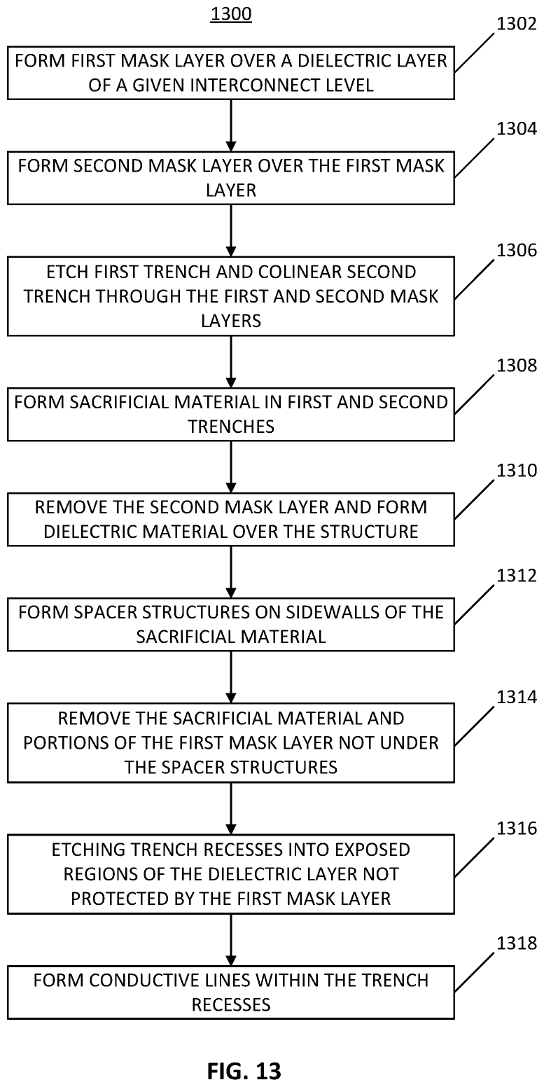

FIG. 13 is a flow chart of a method 1300 for forming at least a portion of an interconnect layer of an integrated circuit, according to an embodiment. Various operations of method 1300 may be illustrated in FIGS. 3A-11A, 3B-11B, and 3C-11C. However, the correlation of the various operations of method 1300 to the specific components illustrated in the aforementioned figures is not intended to imply any structural and/or use limitations. Rather, the aforementioned figures provide one example embodiment of method 1300. Other operations may be performed before, during, or after any of the operations of method 1300. Some of the operations of method 1300 may be performed in a different order than the illustrated order.

Method 1300 begins with operation 1302 where a first mask layer is formed over a dielectric layer at a given interconnect level. In some embodiments, the interconnect level is within the first 3 levels of the interconnect region (e.g., Metal 0 or Metal 1). The first mask layer has a different material composition compared to the underlying dielectric layer. For example, the first mask layer may include silicon nitride and the underlying dielectric layer includes silicon dioxide. The first mask layer may be deposited using any suitable deposition process, such as physical vapor deposition (PVD), CVD, PECVD, or ALD.

Method 1300 continues with operation 1304 where a second mask layer is formed over the first mask layer. The second mask layer has a different material composition compared to the underlying first mask layer. For example, the first mask layer may include silicon nitride and the second mask layer includes silicon dioxide. The second mask layer may include the same material as the dielectric layer. The second mask layer may be deposited using any suitable deposition process, such as PVD, CVD, PECVD, or ALD.

Method 1300 continues with operation 1306 where a first and second colinear trenches are etched through both the first and second mask layers. An RIE process may be used to etch the trenches using suitable photolithographic methods to pattern the locations of the first and second trenches. In some embodiments, the spacing between the opposing ends of the first and second trenches (e.g., ETE spacing) maybe shortened using a directional RIE etch of the second mask layer prior to transferring its pattern into the first mask layer. The first and second trenches may each have a width between about 10 nm and about 15 nm.

Method 1300 continues with operation 1308 where sacrificial material is formed within the first and second trenches. The sacrificial material may be any suitable material that can be removed at a later time without damaging the surrounding material layers. In one example, the sacrificial material is CHM. Other materials such as aluminum oxide may be used as well. According to some embodiments, the sacrificial material is deposited using any suitable vapor deposition technique or spin-on technique and is polished using, for example, CHM such that a top surface of the sacrificial material is substantially coplanar with a top surface of the second mask layer.

Method 1300 continues with operation 1310 where the second mask layer is removed and a spacer material is formed over the interconnect layer. Any suitable isotropic etching process may be used to selectively remove the second mask layer, while the sacrificial material remains. As a result, the sacrificial material extends out of the first and second trenches above a top surface of the first mask layer.

The spacer material may be any suitable dielectric material. In some embodiments, the spacer material has a different material composition compared to the first mask layer to provide an adequate degree of etch selectivity between the first mask layer and the spacer material. In one example, the spacer material includes silicon dioxide and the first mask layer includes silicon nitride or silicon oxynitride. According to some embodiments, the spacer material is deposited using any suitable conformal deposition technique, such ALD. Accordingly, the spacer material forms along the exposed sidewalls of the sacrificial material. The spacer material merges together between the sidewalls of the adjacent, colinear lines of sacrificial material within the first and second trenches.

Method 1300 continues with operation 1312 where spacer structures are formed on sidewalls of the sacrificial material. According to some embodiments, an RIE process is used to remove planar regions of the spacer material while leaving portions of the spacer material on the sidewalls of the sacrificial material. These remaining portions of spacer material form the spacer structures.

Method 1300 continues with operation 1314 where the sacrificial material is removed and portions of the first mask layer not protected by the spacer structures are also removed. According to some embodiments, the sacrificial material is removed using any suitable isotropic etching or ashing process. Next, an RIE process may be used to etch the exposed portions of the first mask layer not protected by the spacer structures. This RIE process may form additional trenches through the first mask layer that are parallel to the first and second trenches. According to some embodiments, all of the etched trenches through the first mask layer will ultimately be transferred into the underling dielectric layer and filled with conductive material to form the metal lines of the interconnect layer.

Method 1300 continues with operation 1316 where trench recesses are etched into the exposed areas of the dielectric layer not protected by the first mask layer. According to some embodiments, the trench pattern through first mask layer across the interconnect layer is transferred into the underlying dielectric layer using an RIE process. Accordingly, the first and second colinear trench recesses are transferred into the dielectric layer during the RIE process.

Method 1300 continues with operation 1318 where conductive lines (e.g., metal lines) are formed within the trench recesses through the dielectric layer. The first mask layer may be removed prior to depositing the conductive material to form the metal lines. The conductive material of the metal lines can include any suitable metal material, such as any of copper, ruthenium, tungsten, cobalt, molybdenum, and alloys thereof. The conductive material may include a barrier layer that is formed before a metal fill, with the barrier layer including titanium nitride or tantalum nitride.

### Example System

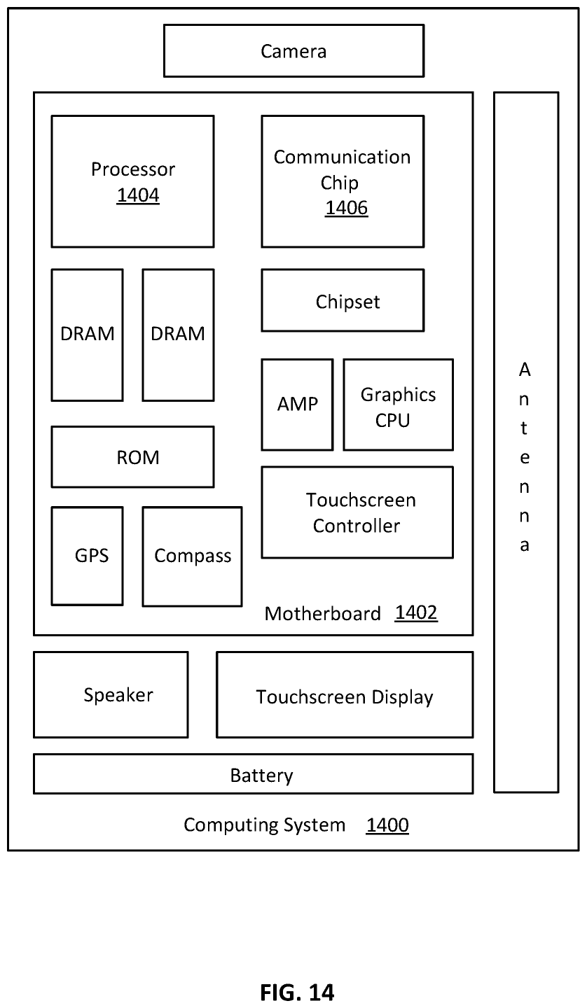

FIG. 14 is an example computing system implemented with one or more of the integrated circuit structures as disclosed herein, in accordance with some embodiments of the present disclosure. As can be seen, the computing system 1400 houses a motherboard 1402. The motherboard 1402 may include a number of components, including, but not limited to, a processor 1404 and at least one communication chip 1406, each of which can be physically and electrically coupled to the motherboard 1402, or otherwise integrated therein. As will be appreciated, the motherboard 1402 may be, for example, any printed circuit board (PCB), whether a main board, a daughterboard mounted on a main board, or the only board of system 1400, etc.

Depending on its applications, computing system 1400 may include one or more other components that may or may not be physically and electrically coupled to the motherboard 1402. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1400 may include one or more integrated circuit structures or devices configured in accordance with an example embodiment (e.g., a module including an integrated circuit having an interconnect layer with a reduced end-to-end spacing between adjacent interconnects). In some embodiments, multiple functions can be integrated into one or more chips (e.g., for instance, note that the communication chip 1406 can be part of or otherwise integrated into the processor 1404).

The communication chip 1406 enables wireless communications for the transfer of data to and from the computing system 1400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1406 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1400 may include a plurality of communication chips 1406. For instance, a first communication chip 1406 may be dedicated to shorter range wireless communications such as Wi-Fi and Bluetooth and a second communication chip 1406 may be dedicated to longer range wireless communications such as GPS, EDGE, GPRS, CDMA, WiMAX, LTE, Ev-DO, and others.

The processor 1404 of the computing system 1400 includes an integrated circuit die packaged within the processor 1404. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 1406 also may include an integrated circuit die packaged within the communication chip 1406. In accordance with some such example embodiments, the integrated circuit die of the communication chip includes one or more semiconductor devices as variously described herein. As will be appreciated in light of this disclosure, note that multi-standard wireless capability may be integrated directly into the processor 1404 (e.g., where functionality of any chips 1406 is integrated into processor 1404, rather than having separate communication chips). Further note that processor 1404 may be a chip set having such wireless capability. In short, any number of processor 1404 and/or communication chips 1406 can be used. Likewise, any one chip or chip set can have multiple functions integrated therein.

In various implementations, the computing system 1400 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 1400 may be combined or integrated in a system-on-a-chip (SoC) architecture. In some embodiments, the components may be hardware components, firmware components, software components or any suitable combination of hardware, firmware or software.

### FURTHER EXAMPLE EMBODIMENTS

The following examples pertain to further embodiments, from which numerous permutations and configurations will be apparent.

Example 1 is an integrated circuit that includes a plurality of semiconductor devices, and an interconnect region above the plurality of semiconductor devices and having a plurality of stacked interconnect layers. An interconnect layer of the plurality of stacked interconnect layers includes a first metal line extending lengthwise along a first direction, a second metal line extending lengthwise collinearly with the first metal line along the first direction, a body of dielectric material between the first metal line and the second metal line along the first direction, and a third metal line extending lengthwise along the first direction adjacent to and parallel with the first metal line and the second metal line. The third metal line includes a protrusion extending outward in a second direction from a sidewall of the third metal line and toward the body of dielectric material.

Example 2 includes the integrated circuit of Example 1, wherein the protrusion extends outward from the sidewall of the third metal line by less than 5 nm.

Example 3 includes the integrated circuit of Example 1 or 2, wherein the protrusion is aligned with a center of the body of dielectric material along the first direction.

Example 4 includes the integrated circuit of any one of Examples 1-3, wherein the protrusion is aligned with the body of dielectric material along the second direction, the second direction being orthogonal to the first direction.

Example 5 includes the integrated circuit of any one of Examples 1-4, wherein the protrusion has an outermost portion that is farthest from the sidewall of the third metal line, and a plane extending in the second direction passes through both the outermost portion of the protrusion and the body of dielectric material, the second direction being orthogonal to the first direction.

Example 6 includes the integrated circuit of any one of Examples 1-5, wherein the protrusion is a first protrusion, and the integrated circuit comprises: a fourth metal line extending lengthwise along the first direction adjacent to and parallel with the first metal line and the second metal line, wherein the fourth metal line includes a second protrusion extending outward in the second direction from a sidewall of the fourth metal line and toward the body of dielectric material.

Example 7 includes the integrated circuit of Example 6, wherein the second protrusion extends outward from the sidewall of the fourth metal line by less than 5 nm.

Example 8 includes the integrated circuit of Example 6 or 7, wherein the second protrusion is aligned with a center of the body of dielectric material along the first direction.

Example 9 includes the integrated circuit of any one of Examples 6-8, wherein the second protrusion is aligned with the body of dielectric material along the second direction, the second direction being orthogonal to the first direction.

Example 10 includes the integrated circuit of any one of Examples 6-9, wherein the second protrusion is aligned with the first protrusion along the second direction, the second direction being orthogonal to the first direction.

Example 11 includes the integrated circuit of any one of Examples 6-10, wherein the first protrusion has an outermost portion that is farthest from the sidewall of the third metal line, and the second protrusion has an outermost portion that is farthest from the sidewall of the fourth metal line, and a plane extending in the second direction passes through each of the outermost portion of the first protrusion, the outermost portion of the second protrusion, and the body of dielectric material, the second direction being orthogonal to the first direction.

Example 12 includes the integrated circuit of any one of Examples 1-11, wherein each of the first, second, and third metal lines comprise tungsten, ruthenium, molybdenum, or cobalt.

Example 13 includes the integrated circuit of any one of Examples 1-12, wherein the body of dielectric material comprises silicon and oxygen.

Example 14 includes the integrated circuit of any one of Examples 1-13, wherein a pitch between the first metal line and the third metal line along the second direction is between about 15 nm and about 25 nm.

Example 15 includes the integrated circuit of any one of Examples 1-14, wherein a length of the body of dielectric material along the first direction is between about 10 nm and about 15 nm.

Example 16 includes the integrated circuit of any one of Examples 1-15, wherein the interconnect layer is a first or second interconnect layer directly above the plurality of semiconductor devices.

Example 17 is a printed circuit board comprising the integrated circuit of any one of Examples 1-16.

Example 18 is an integrated circuit that includes an interconnect region above a plurality of semiconductor devices and having a plurality of stacked interconnect layers. An interconnect layer of the plurality of stacked interconnect layers includes a dielectric layer and a plurality of metal lines within at least a portion of the dielectric layer. The plurality of metal lines include a first metal line extending lengthwise along a first direction and a second metal line extending lengthwise along the first direction adjacent to and parallel with the first metal line. The second metal line includes a protrusion extending outward from a sidewall of the second metal line. The dielectric layer includes a dielectric plug at an end of the first metal line along the first direction. The protrusion is aligned with the dielectric plug along a second direction orthogonal to the first direction.

Example 19 includes the integrated circuit of Example 18, wherein the protrusion extends outward from the sidewall by less than 5 nm.

Example 20 includes the integrated circuit of Example 18 or 19, wherein the protrusion is aligned with a center of the dielectric plug along the first direction.

Example 21 includes the integrated circuit of any one of Examples 18-20, wherein each of the first and second metal lines comprise tungsten, ruthenium, molybdenum, or cobalt.

Example 22 includes the integrated circuit of any one of Examples 18-21, wherein the dielectric plug comprises silicon and oxygen.

Example 23 includes the integrated circuit of any one of Examples 18-22, wherein a pitch between the first metal line and the second metal line along the second direction is between about 15 nm and about 25 nm.

Example 24 includes the integrated circuit of any one of Examples 18-23, wherein a length of the dielectric plug along the first direction is between about 10 nm and about 15 nm.

Example 25 includes the integrated circuit of any one of Examples 18-24, wherein the interconnect layer is a first interconnect layer directly above the plurality of semiconductor devices.

Example 26 includes the integrated circuit of any one of Examples 18-25, further comprising a third metal line extending lengthwise collinearly with the first metal line along the first direction, such that the dielectric plug is directly between the first metal line and the third metal line along the first direction.

Example 27 is a printed circuit board comprising the integrated circuit of any one of Examples 18-26.

Example 28 is an electronic device that includes a chip package having one or more dies. At least one of the one or more dies includes a plurality of semiconductor devices, an interconnect region above the plurality of semiconductor devices and having a plurality of stacked interconnect layers, and an interconnect layer of the plurality of stacked interconnect layers. The interconnect layer includes a first metal line extending lengthwise along a first direction, a second metal line extending lengthwise collinearly with the first metal line along the first direction, a dielectric plug between the first metal line and the second metal line along the first direction, and a third metal line extending lengthwise along the first direction adjacent to and parallel with the first metal line and the second metal line. The third metal line includes a protrusion extending outward from a sidewall of the third metal line. The protrusion is aligned with the dielectric plug along a second direction orthogonal to the first direction.

Example 29 includes the electronic device of Example 28, wherein the protrusion extends outward from the sidewall by less than 5 nm.

Example 30 includes the electronic device of Example 28 or 29, wherein the protrusion is aligned with a center of the dielectric plug along the first direction.

Example 31 includes the electronic device of any one of Examples 28-30, wherein each of the first, second, and third metal lines comprise tungsten, ruthenium, molybdenum, or cobalt.

Example 32 includes the electronic device of any one of Examples 28-31, wherein the dielectric plug comprises silicon and oxygen.

Example 33 includes the electronic device of any one of Examples 28-32, wherein a pitch between the first metal line and the third metal line along the second direction is between about 15 nm and about 25 nm.

Example 34 includes the electronic device of any one of Examples 28-33, wherein a length of the dielectric plug along the first direction is between about 10 nm and about 15 nm.

Example 35 includes the electronic device of any one of Examples 28-34, wherein the interconnect layer is a first interconnect layer directly above the plurality of semiconductor devices.

Example 36 includes the electronic device of any one of Examples 28-35, further comprising a printed circuit board, wherein the chip package is attached to the printed circuit board.

Example 37 is a method of forming an interconnect layer of an integrated circuit. The method includes forming a first mask layer over a dielectric layer, forming a second mask layer over the first mask layer, etching the first and second mask layers to form a first trench and a second trench through both the first and second mask layers with the first trench extending collinearly with the second trench along a first direction and with a portion of the first and second mask layers between the first trench and the second trench along the first direction, filling the first trench and the second trench with a sacrificial material, removing the second mask layer, forming a dielectric material over the first mask layer and over the sacrificial material, etching the dielectric material such that the dielectric material remains on sidewalls of the sacrificial material, removing the sacrificial material, removing portions of the first mask layer not protected by the dielectric material, etching trench recesses into regions of the dielectric layer not protected by the first mask layer, and forming conductive lines within the trench recesses.

Example 38 includes the method of Example 37, wherein filling the first trench and the second trench with a sacrificial material comprises filling the first trench and the second trench with carbon hard mask (CHM).

Example 39 includes the method of Example 37 or 38, wherein etching the dielectric material comprises using a reactive ion etching (RIE) process to anisotropically etch the dielectric material.

Example 40 includes the method of any one of Examples 37-39, wherein the dielectric material comprises silicon and oxygen.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit, comprising:
a plurality of semiconductor devices; and
an interconnect region above the plurality of semiconductor devices, the interconnect region comprising a plurality of stacked interconnect layers;
wherein an interconnect layer of the plurality of stacked interconnect layers includes
a first metal line extending lengthwise along a first direction,
a second metal line extending lengthwise collinearly with the first metal line along the first direction,
a body of dielectric material between the first metal line and the second metal line along the first direction, and
a third metal line extending lengthwise along the first direction adjacent to and parallel with the first metal line and the second metal line, wherein the third metal line includes a protrusion extending outward in a second direction from a sidewall of the third metal line and toward the body of dielectric material.

2. The integrated circuit of claim 1, wherein the protrusion extends outward from the sidewall of the third metal line by less than 5 nm.

3. The integrated circuit of claim 1, wherein the protrusion is aligned with a center of the body of dielectric material along the first direction.

4. The integrated circuit of claim 1, wherein the protrusion has an outermost portion that is farthest from the sidewall of the third metal line, and a plane extending in the second direction passes through both the outermost portion of the protrusion and the body of dielectric material, the second direction being orthogonal to the first direction.

5. The integrated circuit of claim 1, wherein the protrusion is a first protrusion, and the integrated circuit comprises: a fourth metal line extending lengthwise along the first direction adjacent to and parallel with the first metal line and the second metal line, wherein the fourth metal line includes a second protrusion extending outward in the second direction from a sidewall of the fourth metal line and toward the body of dielectric material.

6. The integrated circuit of claim 5, wherein the second protrusion is aligned with a center of the body of dielectric material along the first direction.

7. The integrated circuit of claim 5, wherein the second protrusion is aligned with the first protrusion along the second direction, the second direction being orthogonal to the first direction.

8. The integrated circuit of claim 5, wherein the first protrusion has an outermost portion that is farthest from the sidewall of the third metal line, and the second protrusion has an outermost portion that is farthest from the sidewall of the fourth metal line, and a plane extending in the second direction passes through each of the outermost portion of the first protrusion, the outermost portion of the second protrusion, and the body of dielectric material, the second direction being orthogonal to the first direction.

9. The integrated circuit of claim 1, wherein a length of the body of dielectric material along the first direction is between about 10 nm and about 15 nm.

10. The integrated circuit of claim 1, wherein the interconnect layer is a first or second interconnect layer directly above the plurality of semiconductor devices.

11. An integrated circuit, comprising:
an interconnect region above a plurality of semiconductor devices, the interconnect region comprising a plurality of stacked interconnect layers; and
an interconnect layer of the plurality of stacked interconnect layers, the interconnect layer comprising
a dielectric layer, and
a plurality of metal lines within at least a portion of the dielectric layer, wherein the plurality of metal lines comprise
a first metal line extending lengthwise along a first direction, and
a second metal line extending lengthwise along the first direction adjacent to and parallel with the first metal line, the second metal line having a protrusion extending outward from a sidewall of the second metal line,
wherein the dielectric layer includes a dielectric plug at an end of the first metal line along the first direction, and wherein the protrusion is aligned with the dielectric plug along a second direction orthogonal to the first direction.

12. The integrated circuit of claim 11, wherein the protrusion is aligned with a center of the dielectric plug along the first direction.

13. The integrated circuit of claim 11, wherein a pitch between the first metal line and the second metal line along the second direction is between about 15 nm and about 25 nm.

14. The integrated circuit of claim 11, further comprising a third metal line extending lengthwise collinearly with the first metal line along the first direction, such that the dielectric plug is directly between the first metal line and the third metal line along the first direction.

15. A printed circuit board comprising the integrated circuit of claim 11.

16. An electronic device, comprising:
a chip package comprising one or more dies, at least one of the one or more dies comprising
a plurality of semiconductor devices;
an interconnect region above the plurality of semiconductor devices, the interconnect region comprising a plurality of stacked interconnect layers; and
an interconnect layer of the plurality of stacked interconnect layers, the interconnect layer comprising
a first metal line extending lengthwise along a first direction,
a second metal line extending lengthwise collinearly with the first metal line along the first direction,
a dielectric plug between the first metal line and the second metal line along the first direction, and
a third metal line extending lengthwise along the first direction adjacent to and parallel with the first metal line and the second metal line, wherein the third metal line includes a protrusion extending outward from a sidewall of the third metal line, the protrusion being aligned with the dielectric plug along a second direction orthogonal to the first direction.

17. The electronic device of claim 16, wherein the protrusion is aligned with a center of the dielectric plug along the first direction.

18. The electronic device of claim 16, wherein a pitch between the first metal line and the third metal line along the second direction is between about 15 nm and about 25 nm.

19. The electronic device of claim 16, wherein a length of the dielectric plug along the first direction is between about 10 nm and about 15 nm.

20. The electronic device of claim 16, wherein the interconnect layer is a first interconnect layer directly above the plurality of semiconductor devices.
